(19) United States
(12) Patent Application Publication
(10) Pub. No.: US 2016/0329272 A1
(43) Pub. Date: Nov. 10, 2016

(54) STACKED SEMICONDUCTOR DEVICE PACKAGE WITH IMPROVED INTERCONNECT BANDWIDTH

(71) Applicant: Intel IP Corporation, Santa Clara, CA (US)

(72) Inventors: Christian GEISSLER, Teugn (DE); Georg SEIDEMANN, Landshut (DE); Klaus REINGRUBER, Langquaid (DE)

(21) Appl. No.: 14/779,967

(22) PCT Filed: Dec. 19, 2014
(86) PCT No.: PCT/US2014/071327

§ 371 Date: Sep. 24, 2015

(51) Int. Cl. H01L 23/498; H01L 23/00; H01L 25/065; H01L 23/528

(52) U.S. Cl. CPC H01L 23/49827; H01L 23/528; H01L 24/13; H01L 24/16; H01L 24/73; H01L 24/81; H01L 24/83; H01L 24/92; H01L 25/065; H01L 2224/13147; H01L 2224/16227; H01L 2224/2919; H01L 2224/32225; H01L 2224/73204; H01L 2224/81203; H01L 2224/81207; H01L 2224/81815; H01L 2224/83851; H01L 2224/92125; H01L 2225/06517; H01L 2225/06572

(57) ABSTRACT

The present disclosure describes embodiments of a stacked semiconductor device package and associated techniques and configurations. A package may include a packaging substrate having interconnects and a first semiconductor device attached to one side and a second semiconductor device attached to the opposite side. The devices may be attached in a flip chip configuration with pad sides facing each other on opposite sides of the substrate. The devices may be electrically coupled by the interconnects. The devices may be electrically coupled to fan out pads on the substrate. A dielectric layer may be coupled to the second side of the substrate and encapsulate the second device. Vias may route electrical signals from the fan out area through the dielectric layer and into a redistribution layer coupled to the dielectric layer. Other embodiments may be described and/or claimed.

### FIELD

Embodiments of the present disclosure generally relate to the field of packaging for semiconductor devices, and more particularly, to a stacked semiconductor device package with improved interconnect bandwidth.

### BACKGROUND

Semiconductor device packages with reduced form factor (planar and z-direction), lower power, and lower cost for wearables and mobile applications raise a variety of challenges. For example, 3D chip stacking and package on package stacking are typical solutions to reduce planar (x, y-direction) form factor. However, these stacking approaches may result in z-direction challenges for product design. As another example, reduced power consumption may be obtained by wide input-output memories configured as a top package in contrast to using standard memory approaches. This stacking approach generally needs high interconnect bandwidth between top and bottom packages. Achieving the bandwidth may he accomplished using through silicon vias (TSVs) for die stacking approaches or through mold vias (TMVs) and via bars for package on package approaches. However, TSVs generally are costly, and TMVs and via bars in a fanout area generally have limited interconnect bandwidth. Accordingly, approaches to stacked semiconductor packaging that reduce costs, z-height, power consumption, and planar footprint, while maintaining a high number of interconnections available to connect to a printed circuit board (PCB) may be desirable.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a cross-section side view of an example stacked semiconductor device package, in accordance with some embodiments.

FIG. 2 schematically illustrates a cross-section side view of an example stacked semiconductor device package as an integrated circuit (IC) assembly, in accordance with some embodiments.

FIG. 3 schematically illustrates a cross-section side view of an example stacked semiconductor device package with a third semiconductor device, in accordance with some embodiments.

FIG. 4 schematically illustrates a cross-section side view of an example stacked semiconductor device package with an additional flip chip die and a stacked package on package connected by vias, in accordance with some embodiments.

FIG. 5 schematically illustrates a cross-section side view of an example stacked semiconductor device package with a wafer level chip scale package as a first package device, in accordance with some embodiments.

FIG. 6 schematically illustrates a method of making a stacked semiconductor device package, in accordance with some embodiments.

FIG. 7 schematically illustrates a cross section side view of a stacked semiconductor device package during various stages of fabrication, in accordance with some embodiments.

FIG. 8 schematically illustrates a computing device that includes a stacked semiconductor device package as described herein, in accordance with some embodiments.

### DETAILED DESCRIPTION

Embodiments of the present disclosure describe a stacked semiconductor device package and associated techniques and configurations. In the following description, various aspects of the illustrative implementations are described using terms commonly employed by those skilled in the art to convey the substance of their work to others skilled in the art. However, it will be apparent to those skilled in the art that embodiments of the present disclosure may he practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “or embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

As used herein, the term “module” may refer to, be part of, or include an Application Specific Integrated Circuit (ASIC), an electronic circuit, a system-on-chip (SOC), a processor (shared, dedicated, or group), a MEMS device, an integrated passive device, and/or memory (shared, dedicated, or group) that execute one or more software or firmware programs, a combinational logic circuit, and/or other suitable components that provide the described functionality.

FIG. 1 schematically illustrates a cross-section side view of an example stacked semiconductor device package (package) 100, in accordance with some embodiments. In some embodiments, the package 100 may include a substrate 102 electrically and/or physically coupled with a first side 104f of a first semiconductor device 104 on a first side 102a of the substrate 102 and a first side 106f of a second semiconductor device 106 on a second side 102b of the substrate 102. The first side 102a and the second side 102b may be on opposite sides of the substrate 102. A first side 108a of a dielectric layer 108 may be coupled to the second side 102b of substrate 102 and encapsulate the second semiconductor device 106. The dielectric layer 108 may be in contact with a second side 106c of the second semiconductor device 106. The dielectric layer may have electrical routing features 108c for routing electrical signals from the first side 108a of the dielectric layer 108 to a second side 108b of the dielectric layer and may be used to route electrical signals between the first semiconductor device 104, the second semiconductor device 106, and the second side 108b of the dielectric layer 108.

In some embodiments, the substrate 102 may be comprised of a multilayer semiconductor composite substrate having a core, a thin core, or no core (coreless substrate), or any suitable substrate for packaging semiconductor devices. In some embodiments, any substrate type suitable for flip chip packages may be used for the substrate 102. In some embodiments, the substrate 102 has 1.5 and above layers of a multilayer substrate. In some embodiments, the substrate 102 may be made by any industry standard method, including without limitation sequential build-up and Z-stack methods.

The substrate 102 may have electrical routing features 102c and electrical connections points 102e on the first surface 102a and electrical connection points 102f on the second surface 102b. The substrate may have a fan out area 102g on the second surface 102b and may have a fan out area 102d on the first surface 102a. Electrical routing features 102c of substrate 102 may provide electrical communication between the first semiconductor device 104, the second semiconductor device 106, and the connection points 102e, 102f, including fan out areas 102d and 102g. Electrical connection points 102e and 102f may be bumps, pads, pillars, and any other suitable connector for connecting semiconductor devices to a substrate, including combinations of the foregoing. The electrical routing features 108c of the dielectric layer 108 may be in contact with the electrical connection points 102f of fan out area 102g of the substrate 102. In some embodiments, the substrate 102 may include a multi-layer package assembly with integrated components, including without limitation wireless communication. The substrate 102 may include electrical routing features (not shown in FIG. 1) such as, for example, traces, pads, through-holes, vias, or lines configured to route electrical signals to or from the semiconductor devices coupled with substrate 102.

First semiconductor device 104 may be comprised of a die 104d, which may be encapsulated by mold compound 104e, or a similar type of compound. The die 104d may represent a discrete product made from a semiconductor material (e.g., silicon) using semiconductor fabrication techniques such as thin film deposition, lithography, etching, and the like used in connection with forming complementary metal-oxide-semiconductor (CMOS) devices. In some embodiments, the die 104d may be, include, or be a part of a radio frequency (RF) die. In other embodiments, the die may be, include, or be a part of a processor, memory, system on chip (SoC), or application specific integrated circuit (ASIC).

In some embodiments, an underfill material 104g (sometimes referred to as an “encapsulant”) may be disposed between the die 104d and the substrate 102 to promote adhesion and/or protect features of the die 104d and the substrate 102. The underfill material 104g may be composed of an electrically insulative material and may encapsulate at least a portion of the die 104d and/or die-level interconnect structures 104h, as can be seen. In some embodiments, the underfill material 104g is in direct contact with the die-level interconnect structures 104h. In some embodiments, the underfill material 104g has a side 104a that is in direct contact with the substrate 102 on the first surface 102a.

The die 104d can be attached to the substrate 102 according to a wide variety of suitable configurations including, for example, being directly coupled with the substrate 102 in a flip-chip configuration, as depicted. In the flip-chip configuration, a first side 104f is an active side of the die 104d and includes active circuitry (not shown). The first side 104f is attached to the surface 102a of the substrate 102 using die-level interconnect structures 104h such as bumps, pillars, or other suitable structures that may also electrically couple the die 104d with the substrate 102. Suitable structures include, without limitation, micro solder balls. copper pillars, conductive adhesives, and non-conductive adhesives, and combinations thereof. In some embodiments, reflow can be performed to make connections followed by capillary underfill or molded underfill. Thermo compression bonding or thermo sonic bonding may be used in some embodiments. The first side 104f of the die 104d may include transistor devices, and an inactive side/second side 104c may be disposed opposite to the first side/active side 104f, as can be seen.

The die 104d may generally include a semiconductor substrate 104d.1, one or more device layers (hereinafter “device layer 104d.2”), and one or more interconnect layers (hereinafter “interconnect layer 104d.3”). The semiconductor substrate 104d.1 may be substantially composed of a bulk semiconductor material such as, for example, silicon, in some embodiments. The device layer 104d.2 may represent a region where active devices such as transistor devices are formed on the semiconductor substrate 104d.1. The device layer 104d.2 may include, for example, structures such as channel bodies and/or source/drain regions of transistor devices. The interconnect layer 104d.3 may include interconnect structures that are configured to route electrical signals to or from the active devices in the device layer 104d.2. For example, the interconnect layer 104d.3 may include trenches and/or vias to provide electrical routing and/or contacts.

In some embodiments, the die-level interconnect structures 104h may be configured to route electrical signals between the die 104d and other electrical devices. The electrical signals may include, for example, input/output (I/O) signals and/or power/ground signals that are used in connection with operation of the die 104d.

Second semiconductor device 106 may be comprised of a die 106d. The die 106d may represent a discrete product made from a semiconductor material using semiconductor fabrication techniques such as thin film deposition, lithography, etching, and the like used in connection with forming CMOS devices. In some embodiments, the die 104d may be, include, or be a part of a RF die. In other embodiments, the die may be, include, or be a part of a processor, memory, SoC, MEMS, IPDs, or ASIC.

In some embodiments, an underfill material 106g may be disposed between the die 106d and the substrate 102 to promote adhesion and/or protect features of the die 106d and the substrate 102. The underfill material 106g may be composed of an electrically insulative material and may encapsulate at least a portion of the die 106d and/or die-level interconnect structures 106h, as can be seen. In some embodiments, the underfill material 106g is in direct contact with the die-level interconnect structures 106h. In some embodiments, the underfill material 106g is in direct contact 106a with the substrate 102 on the second surface 102b.

The die 106d can be attached to the substrate 102 according to a wide variety of suitable configurations including, for example, being directly coupled with the substrate 102 in a flip-chip configuration, as depicted. In the flip-chip configuration, a first side 106f is an active side of the die 106d and includes active circuitry. The first side 106f is attached to the surface 102b of the substrate 102 using die-level interconnect structures 106h such as bumps, pillars, or other suitable structures that may also electrically couple the die 106d with the substrate 102. Suitable structures include, without limitation, micro solder balls, copper pillars, conductive adhesives, and non-conductive adhesives, and combinations thereof. In some embodiments, reflow can be performed to make connections followed by capillary underfill or molded underfill. Thermo compression bonding or thermo sonic bonding may be used in some embodiments. The first side 106f of the die 106d may include transistor devices, and an inactive side/second side 106c may be disposed opposite to the first side/active side 106f, as can be seen.

The die 106d may generally include a semiconductor substrate 106d.1, one or more device layers 106d.2, and one or more interconnect layers 106d.3. The semiconductor substrate 106d.1 may he substantially composed of a hulk semiconductor material such as, for example, silicon, in some embodiments. The device layer 106d.2 may represent a region where active devices such as transistor devices are formed on the semiconductor substrate 106d.1. The device layer 106d.2 may include, for example, structures such as channel bodies and/or source/drain regions of transistor devices. The interconnect layer 106d.3 may include interconnect structures that are configured to route electrical signals to or from the active devices in the device layer 106d.2. For example, the interconnect layer 106d.3 may include trenches and/or vies to provide electrical routing and/or contacts.

In some embodiments, the die-level interconnect structures 106h may be configured to route electrical signals between the die 106d and other electrical devices. The electrical signals may include, for example, input/output (I/O) signals and/or power/ground signals that are used in connection with operation of the die 106d.

In some embodiments, the first semiconductor device 104 may be comprised of two or more die having the same or similar features as described for die 104d. In some embodiments, the second semiconductor device 106 may be comprised of two or more dies having the same or similar features as described for die 106d. In some embodiments, the two or more dies are stacked. In some embodiments, the two or more dies are side by side. In some embodiments, the two or more die are stacked and side by side. In some embodiments where the second semiconductor device 106 is comprised of two or more dies, the dielectric layer 108 encapsulates the two or more dies.

In some embodiments, the first semiconductor device 104 and the second semiconductor device 106 may be one or more dies, packages, system in package, surface mounted devices (SMD), integrated active devices (IAD), and/or integrated passive devices (IPD). Active and passive devices may include capacitors, inductors, connectors, switches, relays, transistors, op amps, diodes, oscillators, sensors, MEMS devices, communication and networking modules, memory modules, power modules, interface modules, RF modules, and/or RFID modules.

In some embodiments, the first semiconductor device 104 and the substrate 102 are a wafer level chip scale package with a redistribution layer (WLCSP), a fan out wafer level package with a redistribution layer (FOWLP), an embedded wafer level ball grid array package (eWLBGA), or a wafer level fan out panel level package (WFOP)

In some embodiments, the dielectric layer 108 is comprised of multiple dielectric layers. In some embodiments, the dielectric layer 108 is comprised of one or more laminated layers of dielectric material. In some embodiments, the dielectric layer 108 is a coated dielectric material comprised of one or more coatings. In some embodiments, the dielectric layer 108 is molded. In some embodiments, the dielectric layer 108 is one or more layers of Ajinomoto Build-up Film (ABF), fire retardant FR4 materials, fire retardant FR2 materials, resin coated copper (RCC) film, polyimide (PI), poly-(p-phenylene-2,6-benzobisoxazole) (PBO), bisbenzocyclobutene (BCB), passivation film, and mold compound (liquid, sheet, and powder), and combinations thereof. In some embodiments, the passivation film is a WPR® film made by JSR Corporation. WPR is a registered trademark of JSR Corporation, Higashi-Shinbashi 1-chome Minato-ku Tokyo 105-8640 JAPAN. In some embodiments, the dielectric layer 108 is laser drilled to create openings for creating the electrical routing features 108c. In some embodiments, the electrical routing features 108c are created in the openings by a metal plating process, including electroless and/or electroplating processes.

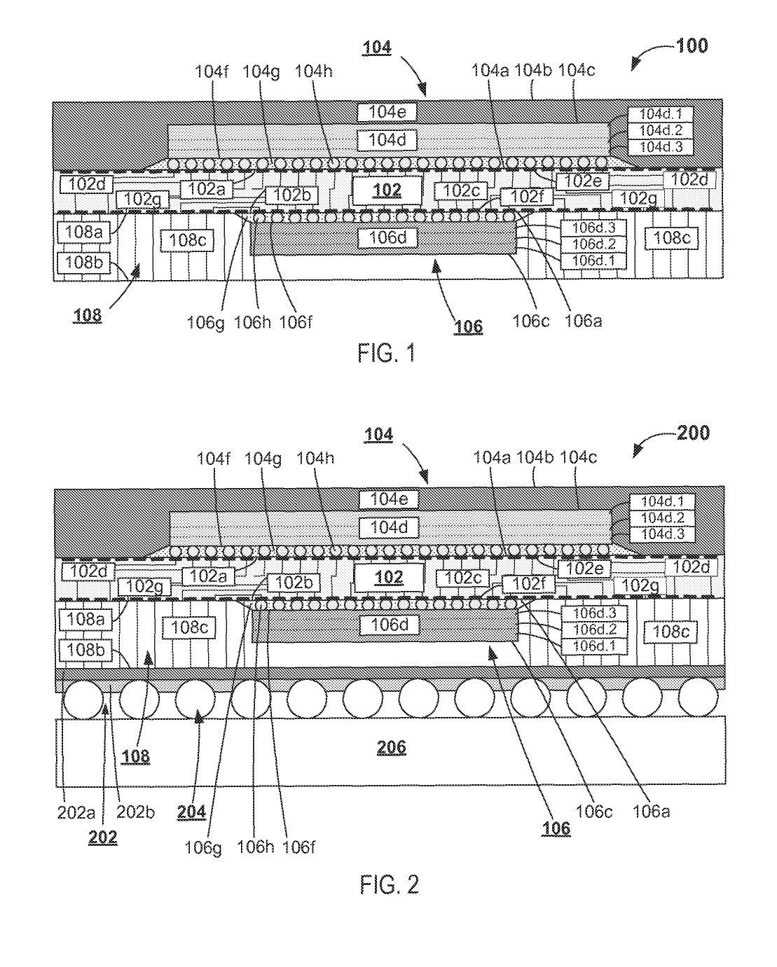

FIG. 2 schematically illustrates a cross-section side view of an example stacked semiconductor device package as an integrated circuit (IC) assembly 200 (IC assembly 200), in accordance with some embodiments. The embodiment of FIG. 2 may comport with embodiments of the stacked semiconductor device package 100 of FIG. 1 with the addition of a redistribution layer 202, interconnect structures 204, and circuit board 206. Accordingly, the description of the components, materials, and methods provided previously for the stacked semiconductor device package 100 of FIG. 1 may apply to the IC assembly 200 of FIG. 2.

In some embodiments, the redistribution layer 202 may be comprised of an electrical signal routing layer 202a and a dielectric layer 202b. In some embodiments, the redistribution layer 202 may be comprised of multiple alternating layers of electrical signal routing layers 202a and dielectric layers 202b. In some embodiments, the dielectric layer 202b is a solder mask layer. In some embodiments, the electrical signal routing layers may be comprised of traces, pads, through-holes, vies, or lines configured to route electrical signals to or from the semiconductor devices coupled with substrate 102 and the circuit board 206.

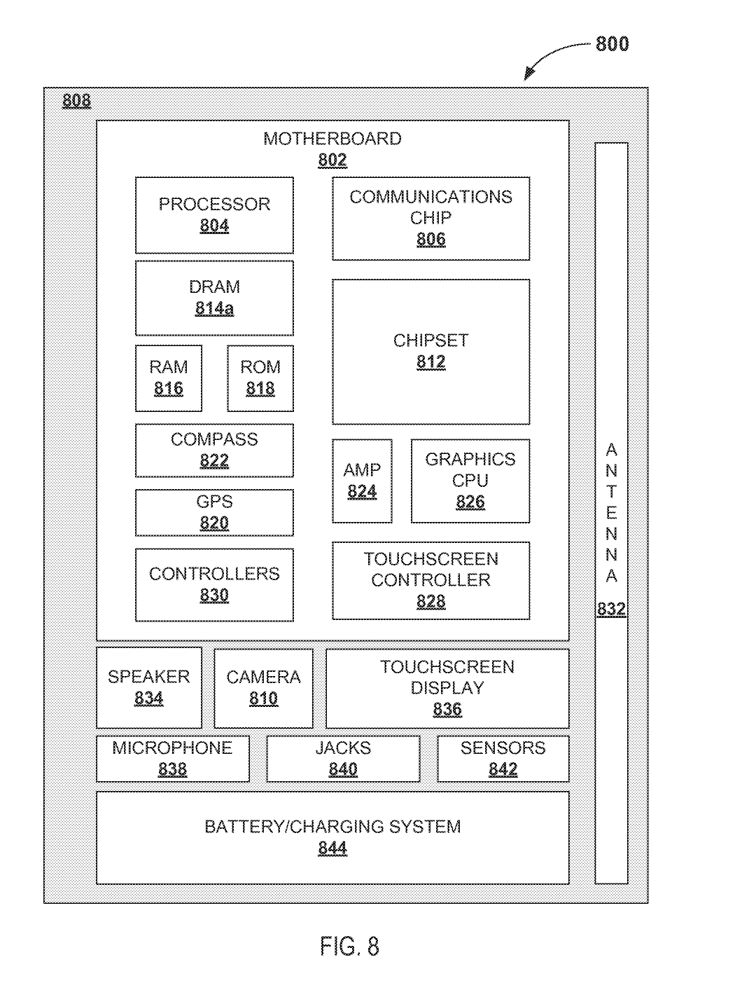

In some embodiments, the circuit board 206 may be a printed circuit board (PCB) composed of an electrically insulative material such as an epoxy laminate. For example, the circuit board 206 may include electrically insulating layers composed of materials such as, for example, polytetrafluoroethylene, phenolic cotton paper materials such as Flame Retardant 4 (FR-4), FR-1, cotton paper, and epoxy materials such as CEM-1 or CEM-3, or woven glass materials that are laminated together using an epoxy resin prepreg material. Interconnect structures (not shown) such as traces, trenches or vies may be formed through the electrically insulating layers to route the electrical signals of semiconductor devices 104d and 106d attached to substrate 102 through the circuit board 206. The circuit board 206 may be composed of other suitable materials in other embodiments. In some embodiments, the circuit board 206 is a motherboard (e.g., motherboard 802 of FIG. 8).

In some embodiments, the interconnect structures 204 may be comprised of bumps, pillars, and/or pads. In some embodiments, the interconnect structures 204 may include solder balls. The interconnect structures 204 may be coupled with the substrate 102 and/or the circuit board 206 to form corresponding solder joints that are configured to further route the electrical signals between the substrate 102 and the circuit board 206. Other suitable techniques to physically and/or electrically couple the substrate 102 with the circuit board 206 may be used in other embodiments.

The IC assembly 200 may include a wide variety of other suitable configurations in other embodiments including, for example, suitable combinations of flip-chip and/or wire-bonding configurations, interposers, multi-chip package configurations including system-in-package (SiP) and/or package-on-package (PoP) configurations. Other suitable techniques to route electrical signals between the die 102 and other components of the IC assembly 200 may be used in some embodiments.

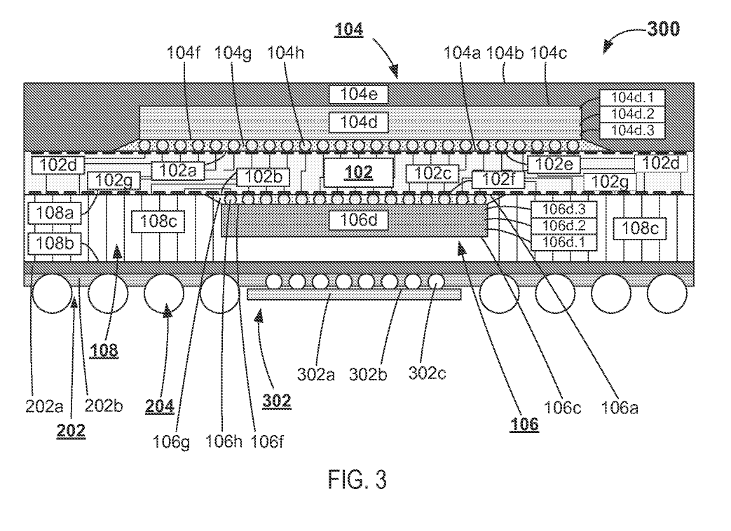

FIG. 3 schematically illustrates a cross-section side view of an example stacked semiconductor device package with a third semiconductor device 300 (package 300), in accordance with some embodiments. The embodiment of FIG. 3 may comport with embodiments of the IC assembly 200 of FIG. 2 with the addition of a third semiconductor device 302 but with removal of the substrate 206 for clarity. Accordingly, the description of the components, materials, and methods provided previously for the stacked semiconductor device package 100 of FIG. 1 and the IC assembly 200 may apply to the package 300 of FIG. 3.

In some embodiments, the third semiconductor device 302 may be comprised of a flip chip die 302a having active surface 302b coupled to redistribution layer 202 by die level interconnect structures 302c, each as previously described. In some embodiments, the third semiconductor device 302 is comprised of two or more semiconductor devices. In some embodiments, the third semiconductor device 302 is comprised of one or more dies, packages, system in package, surface mounted devices (SMD), integrated active devices (IAD), and/or integrated passive devices (IPD). In some embodiments, the third semiconductor device 302 may be a WLCSP, WLP, or a bare die.

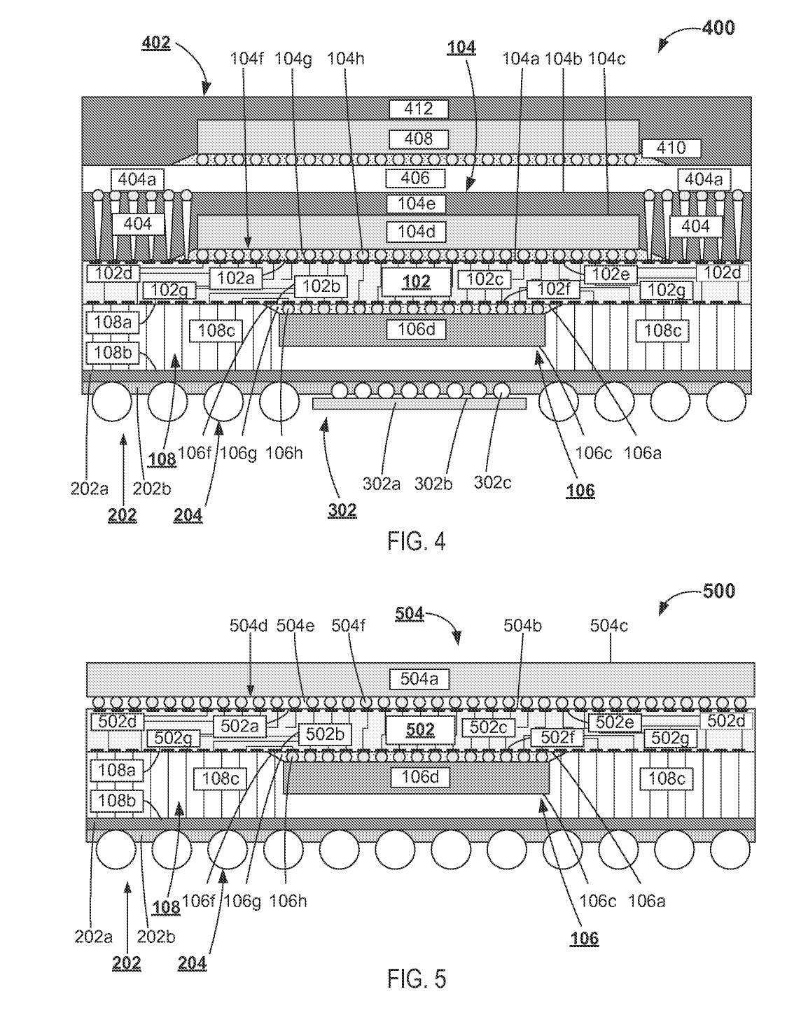

FIG. 4 schematically illustrates a cross-section side view of an example stacked semiconductor device package with an additional flip chip die and a stacked package on package connected by vias 400 (package 400), in accordance with some embodiments. The embodiment of FIG. 4 may comport with embodiments of the package 300 of FIG. 3 with the addition of a fourth semiconductor device 402 stacked on the first semiconductor device 104. Accordingly, the description of the components, materials, and methods provided previously for the package 300 of FIG. 3 may apply to the package 400 of FIG. 4. In some embodiments, the package 400 of FIG. 4 does not have the third semiconductor device 302.

In some embodiments, the fourth semiconductor device 402 is coupled to the first semiconductor device 104 using vias 404 coupled to connection points 102e in fan out area 102d of substrate 102. In some embodiments, interconnections 404a connect the vies 404 to a substrate 406 of the fourth semiconductor device 402. Electrical routing features of substrate 406 are not illustrated in FIG. 4. in some embodiments, the fourth semiconductor device 402 is comprised of a flip chip die 408 on a substrate 406 with interconnects 410 and mold compound 412 encapsulating die 408. In some embodiments, the fourth semiconductor device is a WLCSP or a eWLBGA. in some embodiments, the fourth semiconductor device 402 is coupled to the first semiconductor device 104 by through silicon vias or through mold vias or a combination thereof. In some embodiments, the fourth semiconductor device is comprised of one or more dies, packages, system in package, SMDs, IADs, and/or IPDs. In some embodiments, solder balls may be used to couple device 402.

FIG. 5 schematically illustrates a cross-section side view of an example stacked semiconductor device package with a wafer level chip scale package as a first package device 500 (package 500), in accordance with some embodiments. The embodiment of FIG. 5 may comport with embodiments of the IC assembly 200 of FIG. 2 with the removal of the circuit board 206 and replacement of semiconductor device 104 and substrate 102 by a WLCSP 504 with die 504a and substrate 502. Accordingly, the description of the components, materials, and methods provided previously for the IC assembly 200 of FIG. 3 may apply to the package 500 of FIG. 5.

In some embodiments, the package 500 of FIG. 5 is manufactured using wafer level processes. In some embodiments, the second semiconductor device 106d is coupled to substrate 502 of WLCSP 504 using wafer level processes. In some embodiments, device 106d is coupled to substrate 502 by solder balls, plated micro bumps, solder on pad printing, or copper pillars or other suitable couple structures and methods. In some embodiments, reflow processing is used to couple device 106d. In some embodiments, the dielectric layer is coupled to substrate 502 using wafer level processes such as for example spin on coating of PI, passivation film, and/or PBO.

In some embodiments, first semiconductor device 104 as shown in FIG. 1-3 is a FOWLP. In some embodiments, an RDL is on an artificial wafer or panel with embedded silicon dies followed by attaching of a hanging die on top of the RDL using solder balls, plated micro bumps, solder on pad printing, or copper pillars, or other suitable couple structures and methods. In some embodiments, reflow processing is used to couple device 106d. In some embodiments, the dielectric layer is coupled to substrate 102 using wafer level processes such as for example spin on coating of PI, passivation film, and/or PBO. In some embodiments, artificial panel substrate technology is used with lamination of ABF or similar dielectric film is used to couple the dielectric layer 108 to substrate 102.

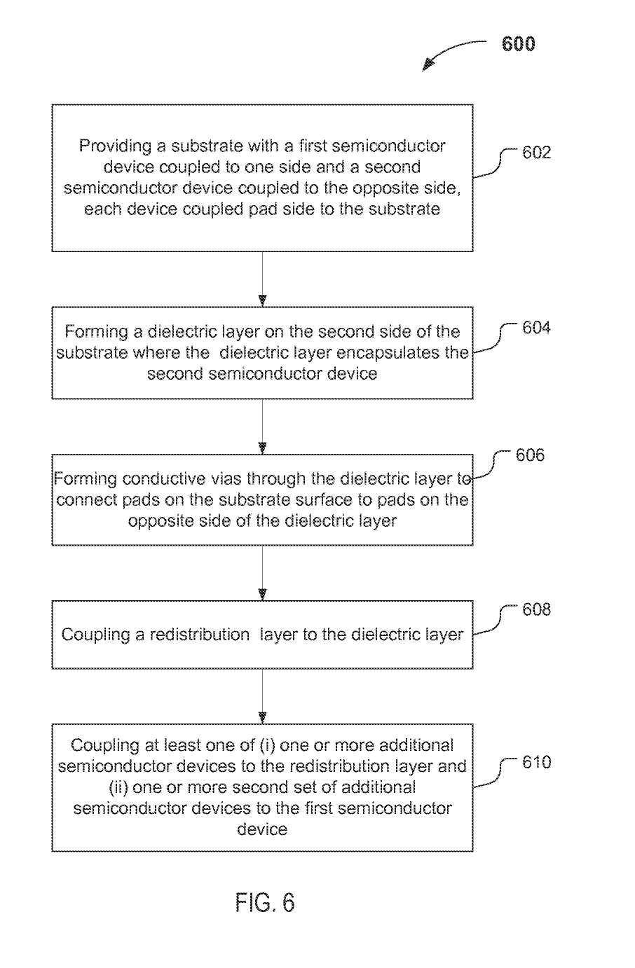

FIG. 6 schematically illustrates a method 600 of making a stacked semiconductor device package, in accordance with some embodiments. The method 600 may be used to make the embodiments illustrated in FIGS. 1-5 for attachment of the embodiments to circuit board 206 shown in FIG. 2. Reference numerals used are those used in FIGS. 1-5.

At 602, the method 600 may include providing a substrate 102, 502 with a first semiconductor device 104, 504 coupled to a first side 102a. 502a and a second semiconductor device 106 coupled to the second/opposite side 102b, 502b of the substrate 102, 502. In some embodiments, the semiconductor devices 104, 504 and 106 may be coupled with active sides facing the substrate in a flip chip configuration, for example. In some embodiments, wafer level processing may be used at 602, including for example WLCSP, eWLBGA, or FOWLP, or the like, where silicon die may be the starting point and then RDL-layers may be added and may be the substrate.

At 604, the method 600 may include forming a dielectric layer 108 on the second side 102b, 502h where the dielectric layer encapsulates the second semiconductor device 106. In some embodiments, wafer level processing may be used to form the dielectric layer 108. In some embodiments, the dielectric layer may be formed by lamination or spin coating or a combination thereof. In some embodiments, laser drilling or another suitable method may be used to create openings in the dielectric layer 108 for making the conductive vias. In some embodiments, the conductive vias may be formed by electroless or electroplating processes, or a combination thereof.

At 608, the method 600 may couple a redistribution layer (RDL) 202 to the dielectric layer 108. In some embodiments, the RDL layer 202 may be two or more layers comprised of a conductive layer and a dielectric layer and may be formed by lamination or coating or a combination thereof, In some embodiments, the stacked semiconductor device package may be coupled to a circuit board 206.

At 610, the method 600 may couple one or more additional semiconductor devices 302 to the RDL 202. In some embodiments, one or more additional semiconductor devices 402 may be coupled to the first semiconductor device 104.

In some embodiments, a coupling area to couple to a circuit board 206 may include all of the area of the RDL 202, including area under the second semiconductor device 106 not in fan out area 102g.

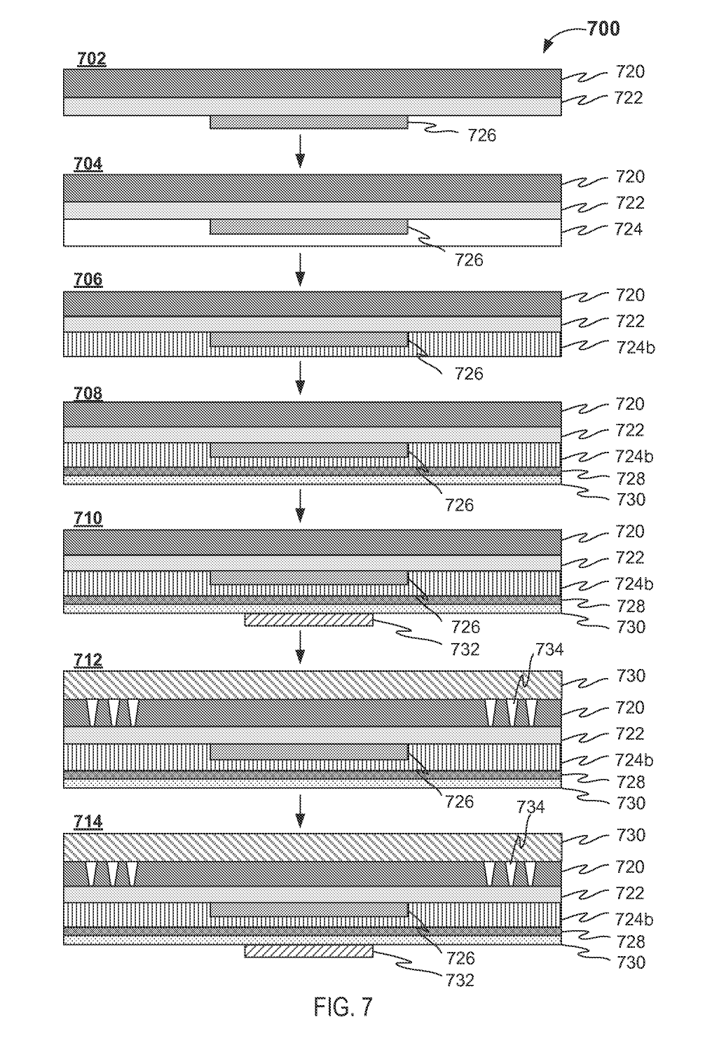

FIG. 7 schematically illustrates a cross section side view of a stacked semiconductor device package during various stages of fabrication, in accordance with some embodiments, and as illustrated by examples shown in FIGS. 1-5 and the method of FIG. 6. The structures of FIG. 7 may have similar reference markings as those in FIGS. 1-5 and are intended to represent similar structures, except where indicated otherwise. Structure 702 corresponds to 602 of method 600. Structure 702 depicts a first semiconductor device 720 coupled to a substrate 722 and a second semiconductor device 726 coupled to the substrate 722. Structure 704 corresponds to 602 of method 600. In structure 704, structure 702 may have a dielectric layer 724 coupled to substrate 722 and encapsulating the second semiconductor device 726. Structure 706 corresponds to 606 in method 600. In structure 706, the dielectric layer 724 may have conductive vias formed through it to form dielectric layer 724b. Structure 708 corresponds to 608 of method 600. In structure 708, a redistribution layer comprised of at least one conductive layer 728 and one dielectric layer 730 may be present. Structure 708 may have solder balls or other coupling structures that are on the RDL and coupled to a circuit board, such as the mother board of FIG. 8. Structure 710 corresponds to 610 of method 600. In structure 710, an additional semiconductor device 732 may be coupled to the RDL. Structure 712 corresponds to 610 of method 600. In structure 712, an additional semiconductor device 730 may be coupled to device 720 by vies 734. Structure 714 corresponds to 610 of method 600. In structure 714, additional semiconductor device 730 may be coupled to device 720 by vias 734 and another additional semiconductor device 732 may be coupled to the RDL.

Various operations are described as multiple discrete operations in turn, in a manner that is most helpful in understanding the claimed subject matter. However, the order of description should not be construed as to imply that these operations are necessarily order dependent.

Embodiments of the present disclosure may be implemented into a system using any suitable hardware and/or software to configure as desired. FIG. 8 schematically illustrates a computing device that includes a stacked semiconductor device package as described herein, in accordance with some embodiments, as shown in FIGS. 1-5 and as previously described. The computing device 800 may house a board such as motherboard 802 (e.g., in housing 808). The motherboard 802 may include a number of components, including but not limited to a processor 804 and at least one communication chip 806. The processor 804 may be physically and electrically coupled to the motherboard 802. In some implementations, the at least one communication chip 806 may also be physically and electrically coupled to the motherboard 802. In further implementations, the communication chip 806 may be part of the processor 804.

Depending on its applications, computing device 800 may include other components that may or may not be physically and electrically coupled to the motherboard 802. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, MEMS sensors, a Geiger counter, an accelerometer, a gyroscope, a speaker, a camera, and a mass storage device (such as hard disk drive, compact disk (CD), digital versatile disk (DVD), and so forth).

The communication chip 806 may enable wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Institute for Electrical and Electronic Engineers (IEEE) standards including WiGig, Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible broadband wireless access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 806 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 806 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 806 may operate in accordance with other wireless protocols in other embodiments.

The computing device 800 may include a plurality of communication chips 806. For instance, a first communication chip 806 may be dedicated to shorter range wireless communications such as WiGig, Wi-Fi and Bluetooth and a second communication chip 806 may be dedicated to longer range wireless communications such as GPS, EDGE, GPRS, CDMA, WiMAX, LTE, EV-DO, and others.

The processor 804 of the computing device 800 may be packaged in an stacked semiconductor device package as described herein and illustrated in FIGS. 1-5. For example, the circuit board 206 of FIG. 2 may be a motherboard 802 and the processor 804 may be a die 104d, 106d, 408, 504a mounted in a stacked semiconductor device package as described in AGS. 1-5. The stacked semiconductor device package and the motherboard 802 may he coupled together using package-level interconnects solder balls, pads, bumps, or pillars, or other suitable interconnects. Other suitable configurations may be implemented in accordance with embodiments described herein. The term “processor” may refer to any device or portion of a device that processes electronic data from registers and/or memory to transform that electronic data into other electronic data that may be stored in registers and/or memory.

The communication chip 806 may also include a die (e.g., RF die) that may be packaged in a stacked semiconductor device package of FIGS. 1-5, as described herein. In further implementations, another component (e.g., memory device or other integrated circuit device) housed within the computing device 800 may include a die that may be packaged in a stacked semiconductor device package of FIGS. 1-5, as described herein.

In various implementations, the computing device 800 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. The computing device 800 may be a mobile computing device in some embodiments.

In further implementations, the computing device 800 may be any other electronic device that processes data.

### EXAMPLES

According to various embodiments, the present disclosure describes a stacked semiconductor device package. Example 1 of a stacked semiconductor device package (package) may include a substrate with a first side and a second side opposite the first side, wherein the first side has a plurality of pads and the second side has a plurality of pads including pads in a second side fan out area, wherein the substrate has electrical routing features configured to electrically couple pads of the plurality of pads on the first side with pads of the plurality of pads on the second side including the pads of the second side fan out area; a first semiconductor device with a first device pad side coupled with a pad of the plurality of pads on the first side of the substrate; a second semiconductor device with a second device pad side coupled with a pad of the plurality of pads on the second side of the substrate, the first semiconductor device and the second semiconductor device being electrically coupled together through the substrate by the electrical routing features; and a dielectric layer having a first side coupled with the second side of the substrate and encapsulating the second semiconductor device, wherein the dielectric layer has a plurality of conductive vias electrically coupled with the pads in the second side fan out area and configured to route electrical signals of the first semiconductor device and the second semiconductor device between the first side of the dielectric layer and a second side of the dielectric layer, the second side of the dielectric layer opposite to the first side of the dielectric layer.

Example 2 may include the package of Example 1, wherein the first semiconductor device is a flip chip die.

Example 3 may include the package of Example 1, wherein the first semiconductor device and the substrate are a combined semiconductor package comprising one or more semiconductor dies.

Example 4 may include the package of Example 3, wherein the combined semiconductor package comprises a wafer level chip scale package, an embedded fan out wafer level package, or a fan in wafer level package.

Example 5 may include the package of Example 1, further comprising at least one of one or more additional semiconductor devices, each with a plurality of pads coupled to a pad of the plurality of pads on the first side of the substrate; and one or more additional semiconductor devices, each with a plurality of pads coupled to a pad of the plurality of pads on the second side of the substrate, the dielectric layer encapsulating the one or more additional semiconductor devices.

Example 6 may include the package of Example 1, further including a mold compound encapsulating the first semiconductor device.

Example 7 may include the package of any of Examples 1-6, wherein the second semiconductor device is a flip chip die, a wafer level chip scale package, a wafer level package, an embedded wafer level package, or a panel level package.

Example 8 may include the package of Example 1, further including a redistribution layer having a first side coupled with the second side of the dielectric layer, wherein the redistribution layer has a plurality of conductive pathways that electrically couple the plurality of conductive vias to a plurality of pads on a second side of the redistribution layer, the second side of the redistribution layer opposite to the first side of the redistribution layer, the plurality of pads on the second side of the redistribution layer include pads underneath an area of the second semiconductor device.

Example 9 may include the package of Example 8, further including at least one of one or more additional semiconductor devices, each with a plurality of pads coupled to a pad of the plurality of pads on the second side of the redistribution layer; and one or more second set of additional semiconductor devices, each with a plurality of pads, at least one of the pads coupled to a pad of a plurality of pads on a second side of the first semiconductor device, the second side opposite the first device pad side, the plurality of pads on the second side of the first semiconductor device coupled to the substrate by a first device plurality of conductive pathways.

Example 10 may include the package of Example 1, wherein the first semiconductor device and the second semiconductor device are each one or more devices selected from the group consisting of semiconductor dies, passive semiconductor devices, active semiconductor devices, semiconductor packages, semiconductor modules, surface mounted semiconductor devices, and integrated passive devices, and combinations thereof.

Example 11 may include the package of Example 1, wherein the dielectric layer is comprised of one or more layers of polymeric or polymeric composite materials.

Example 12 may include the package of Example 11, wherein the polymeric or polymeric composite materials are selected from the group consisting of Ajinomoto Build-up Film (ABF), fire retardant FR2, fire retardant FR4, resin coated copper (RCC) foil, polyimide, passivation film, poly benzthiazole (PBZT), poly benzoxazole (PBO), and mold compound, and combinations thereof.

Example 13 of a method of making a stacked semiconductor device package (method) may include providing a substrate with a first side and a second side opposite the first side, the first side having a plurality of pads, the second side having a plurality of pads, and a first semiconductor device with a first device pad side having a pad coupled to the plurality of pads on the first side of the substrate and a second semiconductor device with a second device pad side having a pad coupled to the plurality of pads on the second side of the substrate; and forming a dielectric layer on the second side of the substrate, the dielectric layer encapsulating the second semiconductor device, forming further comprising laminating, coating, or a combination of laminating and coating one or more polymeric or polymeric composite materials.

Example 14 may include the method of Example 13, wherein the polymeric or polymeric composite materials are selected from the group consisting of Ajinomoto Build-up Film (ABF), fire retardant FR2, fire retardant FR4, resin coated copper (RCC) foil, polyimide, passivation film, poly benzthiazole (PBZT), poly benzoxazole (PBO), and mold compound, and combinations thereof.

Example 15 may include the method of Example 13, wherein a first side of the dielectric layer is coupled with the second side of the substrate, the method further include forming conductive vias through the dielectric layer to connect at least one of the plurality of pads on the second side of the substrate to at least one of a plurality of pads on a second side of the dielectric layer, the second side of the dielectric layer opposite the first side of the dielectric layer.

Example 16 may include the method of Example 13, further including forming a redistribution layer coupled to the second side of the dielectric layer.

Example 17 may include the method of Example 13, further comprising at least one of coupling one or more additional semiconductor devices each with pad sides to a pad of a plurality of pads on the redistribution layer; and coupling one or more second set of additional semiconductor devices, each with a plurality of pads, at least one of the pads coupled to a pad of a plurality of pads on a second side of the first semiconductor device, the second side opposite the first device pad side, the plurality of pads on the second side of the first semiconductor device coupled to the substrate by a first device plurality of conductive pathways.

Example 18 of a computing device (device) may include a circuit board; and a stacked semiconductor device package including a substrate with a first side and a second side opposite the first side, wherein the first side has a plurality of pads and the second side has a plurality of pads including pads in a second side fan out area, wherein the substrate has electrical routing features configured to electrically couple pads of the plurality of pads on the first side with pads of the plurality of pads on the second side including the pads of the second side fan out area; a first semiconductor device with a first device pad side coupled with a pad of the plurality of pads on the first side of the substrate; a second semiconductor device with a second device pad side coupled with a pad of the plurality of pads on the second side of the substrate, the first semiconductor device and the second semiconductor device being electrically coupled together through the substrate by the electrical routing features; a dielectric layer having a first side coupled with the second side of the substrate and encapsulating the second semiconductor device, wherein the dielectric layer has a plurality of conductive vies electrically coupled with the pads in the second side fan out area and configured to route electrical signals of the first semiconductor device and the second semiconductor device between the first side of the dielectric layer and a second side of the dielectric layer, the second side of the dielectric layer opposite to the first side of the dielectric layer; and a redistribution layer having a first side coupled with the second side of the dielectric layer, wherein the redistribution layer has a plurality of conductive pathways that electrically couple the plurality of conductive vies to a plurality of pads on a second side of the redistribution layer, the second side of the redistribution layer opposite to the first side of the redistribution layer, the second side of the redistribution layer electrically coupled to the circuit board, the plurality of pads on the second side of the redistribution layer include pads underneath an area of the second semiconductor device.

Example 19 may include the device of Example 18, wherein the first semiconductor device is a flip chip die encapsulated in a mold compound.

Example 20 may include the device of Example 18, wherein the first semiconductor device and the substrate are a combined semiconductor package comprising one or more semiconductor dies.

Example 21 may include the device of Example 20, wherein the combined semiconductor package includes a wafer level chip scale package, an embedded fan out wafer level package, or a fan in wafer level package.

Example 22 may include the device of Example 18, further comprising at least one of one or more additional semiconductor devices, each with a plurality of pads, at least one of the pads coupled to a pad of the plurality of pads on the first side of the substrate; and one or more additional semiconductor devices, each with a plurality of pads, at least one of the pads coupled to a pad of the plurality of pads on the second side of the substrate, the dielectric layer encapsulating the one or more additional semiconductor devices. Example 23 may include the device of Example 18 further including a mold compound encapsulating the first semiconductor device.

Example 24 may include the device of any of Examples 18-23, wherein the second semiconductor device is a flip chip die, a wafer level chip scale package, a wafer level package, an embedded wafer level package, or a panel level package,

Example 25 may include the device of Example 18, further including at least one of one or more additional semiconductor devices, each with a plurality of pads, at least one of the pads coupled to a pad of the plurality of pads on the second side of the redistribution layer; and one or more second set of additional semiconductor devices, each with a plurality of pads, at least one of the pads coupled to a pad of a plurality of pads on a second side of the first semiconductor device, the second side opposite the first device pad side, the plurality of pads on the second side of the first semiconductor device coupled to the substrate by a first device plurality of conductive pathways.

Example 26 may include the device of Example 18, wherein the first semiconductor device and the second semiconductor device are each one or more devices selected from the group consisting of semiconductor dies, passive semiconductor devices, active semiconductor devices, semiconductor packages, semiconductor modules, surface mounted semiconductor devices, and integrated passive devices, and combinations thereof.

Example 27 may include the device of Example 18, wherein the dielectric layer is comprised of one or more layers of polymeric or polymeric composite materials.

Example 28 may include the device of Example 27, wherein the materials are selected from the group consisting of Ajinomoto Build-up Film (ABF), FR2, FR4, resin coated copper (RCC) foil, polyimide, WPR, poly benzthiazole (PBZT), poly benzoxazole (PBO), and mold compound, and combinations thereof.

Example 29 may include the device of Example 18, wherein the computing device is a wearable device or a mobile computing device, the wearable device or the mobile computing device including one or more of an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, or a camera coupled with the circuit board.

Example 30 may include the device of Example 18, where the circuit board is comprised of a flexible material.

1-25. (canceled)

26. A stacked semiconductor device package, comprising:
a substrate with a first side and a second side opposite the first side, wherein the first side has a plurality of pads and the second side has a plurality of pads including pads in a second side fan out area, wherein the substrate has electrical routing features configured to electrically couple pads of the plurality of pads on the first side with pads of the plurality of pads on the second side including the pads of the second side fan out area;
a first semiconductor device with a first device pad side coupled with a pad of the plurality of pads on the first side of the substrate;
a second semiconductor device with a second device pad side coupled with a pad of the plurality of pads on the second side of the substrate, the first semiconductor device and the second semiconductor device being electrically coupled together through the substrate by the electrical routing features; and
a dielectric layer having a first side coupled with the second side of the substrate and encapsulating the second semiconductor device, wherein the dielectric layer has a plurality of conductive vias electrically coupled with the pads in the second side fan out area and configured to route electrical signals of the first semiconductor device and the second semiconductor device between the first side of the dielectric layer and a second side of the dielectric layer, the second side of the dielectric layer opposite to the first side of the dielectric layer.

27. The package of claim 26, wherein the first semiconductor device is a flip chip die.

28. The package of claim 26, wherein the first semiconductor device and the substrate are a combined semiconductor package comprising one or more semiconductor dies.

29. The package of claim 28, wherein the combined semiconductor package comprises a wafer level chip scale package, an embedded fan out wafer level package, or a fan in wafer level package.

30. The package of claim 26, further comprising at least one of:
one or more additional semiconductor devices, each with a plurality of pads coupled to a pad of the plurality of pads on the first side of the substrate; and
one or more additional semiconductor devices, each with a plurality of pads coupled to a pad of the plurality of pads on the second side of the substrate, the dielectric layer encapsulating the one or more additional semiconductor devices.

31. The package of claim 26, further comprising:
a mold compound encapsulating the first semiconductor device.

32. The package of claim 26, wherein the second semiconductor device is a flip chip die, a wafer level chip scale package, a wafer level package, an embedded wafer level package, or a panel level package.

33. The package of claim 26, further comprising:
a redistribution layer having a first side coupled with the second side of the dielectric layer, wherein the redistribution layer has a plurality of conductive pathways that electrically couple the plurality of conductive vias to a plurality of pads on a second side of the redistribution layer, the second side of the redistribution layer opposite to the first side of the redistribution layer, the plurality of pads on the second side of the redistribution layer include pads underneath an area of the second semiconductor device.

34. A method of making a stacked semiconductor device package, the method comprising:
providing a substrate with a first side and a second side opposite the first side, the first side having a plurality of pads, the second side having a plurality of pads, and a first semiconductor device with a first device pad side having a pad coupled to the plurality of pads on the first side of the substrate and a second semiconductor device with a second device pad side having a pad coupled to the plurality of pads on the second side of the substrate; and
forming a dielectric layer on the second side of the substrate, the dielectric layer encapsulating the second semiconductor device, forming further comprising laminating, coating, or a combination of laminating and coating one or more polymeric or polymeric composite materials.

35. The method of claim 34, wherein a first side of the dielectric layer is coupled with the second side of the substrate, the method further comprising:
forming conductive vias through the dielectric layer to connect at least one of the plurality of pads on the second side of the substrate to at least one of a plurality of pads on a second side of the dielectric layer, the second side of the dielectric layer opposite the first side of the dielectric layer.

36. The method of claim 34, further comprising:
forming a redistribution layer coupled to the second side of the dielectric layer.

37. A computing device, comprising:
a circuit board; and
a stacked semiconductor device package, comprising:
a substrate with a first side and a second side opposite the first side, wherein the first side has a plurality of pads and the second side has a plurality of pads including pads in a second side fan out area, wherein the substrate has electrical routing features configured to electrically couple pads of the plurality of pads on the first side with pads of the plurality of pads on the second side including the pads of the second side fan out area;
a first semiconductor device with a first device pad side coupled with a pad of the plurality of pads on the first side of the substrate;
a second semiconductor device with a second device pad side coupled with a pad of the plurality of pads on the second side of the substrate, the first semiconductor device and the second semiconductor device being electrically coupled together through the substrate by the electrical routing features;
a dielectric layer having a first side coupled with the second side of the substrate and encapsulating the second semiconductor device, wherein the dielectric layer has a plurality of conductive vias electrically coupled with the pads in the second side fan out area and configured to route electrical signals of the first semiconductor device and the second semiconductor device between the first side of the dielectric layer and a second side of the dielectric layer, the second side of the dielectric layer opposite to the first side of the dielectric layer; and
a redistribution layer having a first side coupled with the second side of the dielectric layer, wherein the redistribution layer has a plurality of conductive pathways that electrically couple the plurality of conductive vias to a plurality of pads on a second side of the redistribution layer, the second side of the redistribution layer opposite to the first side of the redistribution layer, the second side of the redistribution layer electrically coupled to the circuit board, the plurality of pads on the second side of the redistribution layer include pads underneath an area of the second semiconductor device.

38. The computing device of claim 37, wherein the first semiconductor device is a flip chip die encapsulated in a mold compound.

39. The computing device of claim 37, wherein the first semiconductor device and the substrate are a combined semiconductor package comprising one or more semiconductor dies.

40. The computing device of claim 39, wherein the combined semiconductor package comprises a wafer level chip scale package, an embedded fan out wafer level package, or a fan in wafer level package.

41. The computing device of claim 37, further comprising at least one of:
one or more additional semiconductor devices, each with a plurality of pads, at least one of the pads coupled to a pad of the plurality of pads on the first side of the substrate; and
one or more additional semiconductor devices, each with a plurality of pads, at least one of the pads coupled to a pad of the plurality of pads on the second side of the substrate, the dielectric layer encapsulating the one or more additional semiconductor devices.

42. The computing device of claim 37, further comprising:
a mold compound encapsulating the first semiconductor device.

43. The computing device of claim 37, wherein the second semiconductor device is a flip chip die, a wafer level chip scale package, a wafer level package, an embedded wafer level package, or a panel level package. (New) The computing device of claim 37, wherein the computing device is a wearable device or a mobile computing device, the wearable device or the mobile computing device including one or more of an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, or a camera coupled with the circuit board.

45. The computing device of claim 37, where the circuit board is comprised of a flexible material.
